(19) United States
(12) Patent Application Publication
(10) Pub. No.: US 2013/0210225 A1
(43) Pub. Date: Aug. 15, 2013

(54) METHOD FOR FABRICATING SEMICONDUCTOR DEVICE

(71) Applicant: Jin-Ku LEE, Gyeonggi-do (KR)

(72) Inventor: Jin-Ku LEE, Gyeonggi-do (KR)

(21) Appl. No.: 13/468,116

(22) Filed: May 10, 2012

(30) Foreign Application Priority Data
Feb. 15, 2012 (KR) 10-2012-0015328

(51) Int. Cl. H01L 21/768

(52) U.S. Cl. 438/653; 257/E21.584

(57) ABSTRACT

A method for fabricating a semiconductor device includes etching a substrate to form a pillar isolated by a trench, forming a buffer layer along the entire structure including the pillar, forming a diffusion barrier layer that exposes a portion of the buffer layer at a first sidewall of the pillar, forming a liner layer along the entire structure including the diffusion barrier layer, selectively ion-implanting dopants into the liner layer, and forming a junction in the first sidewall of the pillar by diffusing the dopants through a thermal process.

### CROSS-REFERENCE TO RELATED APPLICATIONS

The present application claims priority of Korean Patent Application No. 10-2012-0015328, filed on Feb. 15, 2012, which is incorporated herein by reference in its entirety.

### BACKGROUND

1. Field

Exemplary embodiments of the present invention relate to semiconductor fabrication technology, and more particularly, to a method for fabricating a buried bit line of a semiconductor device.

2. Description of the Related Art

The design of MOSFET devices having a flat structure has approached physical limits in leakage current, driving current, and single channel effects obtained by shrinking the size of the devices. Accordingly, further shrinking of the devices may be difficult. To address these difficulties, research has been conducted on a vertical gate using a vertical channel instead of a horizontal channel.

In order to implement a vertical gate using a vertical channel, a sidewall of a pillar should be exposed to be contacted with a metal bit line buried between two pillars. This process is referred to as a single-side-contact (SSC) process or one-side-contact (OSC) process. For illustration purposes, the process is collectively referred to as the SSC process. In the SSC process, a source formed in the pillar is exposed, and a buried bit line is electrically coupled to the exposed source.

A single side contact is formed as follows. First, a liner layer is deposited on the pillar, and a tilt ion implantation process is performed to implant dopants into a first surface of the liner layer deposited on the pillar. Subsequently, a contact region is opened by removing the liner layer that is not implanted with dopants using an to etch rate difference between the dopant-implanted portion and the non-implanted portion, and a junction region capable of contacting with a metal bit line is formed in one surface of the pillar.

However, during the SSC formation using the tilt ion implantation process, a double side contact may occur depending on a process condition or the like. Furthermore, since the junction region is formed after the contact region is opened, junctions are formed in both open regions of the pillar, and a bridge may be formed between bit lines during a subsequent process. Therefore, an electrical characteristic may be degraded, and the implementation of the vertical gate may be difficult.

In addition, research is being conducted on a junction formation method including a method that forms a junction by burying doped polysilicon and diffusing dopants through a thermal process and a method that performs conformal doping using plasma doping.

However, when the doped polysilicon is used, the diffusion may be difficult to suppress. Thus, a floating body may be formed. In addition, the doped polysilicon may be difficult to remove. Furthermore, when the plasma doping is applied, constantly maintaining uniformity within a wafer may also be difficult.

### SUMMARY

An embodiment of the present invention is directed to a method for fabricating a semiconductor device capable of forming a uniform junction and preventing a bridge between bit lines.

In accordance with an embodiment of the present invention, a method for fabricating a semiconductor device includes: etching a substrate to form a pillar isolated by a trench; forming a buffer layer along the entire structure including the pillar; forming a diffusion barrier layer that exposes a portion of the buffer layer at a first sidewall of the pillar; forming a liner layer along the entire structure including the diffusion barrier layer; selectively ion-implanting dopants into the liner layer; and forming a junction in the first sidewall of the pillar by diffusing the dopants through a thermal process.

In accordance with another embodiment of the present invention, a method for fabricating a semiconductor device includes: forming a buffer layer over a substrate; forming a diffusion barrier layer pattern over the buffer layer to expose a portion of the buffer layer; forming a liner layer along the entire structure including the diffusion barrier layer; ion-implanting dopants into the liner layer; and forming a shallow junction in the substrate by diffusing the dopants through a thermal process.

### BRIEF DESCRIPTION OF THE DRAWINGS

FIGS. 1A to 1G are cross-sectional views illustrating a method for fabricating a semiconductor device in accordance with an embodiment of the present invention.

FIGS. 2A to 2H are cross-sectional views illustrating an SSC process and a buried bit line process that are performed after a process of FIG. 1G

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

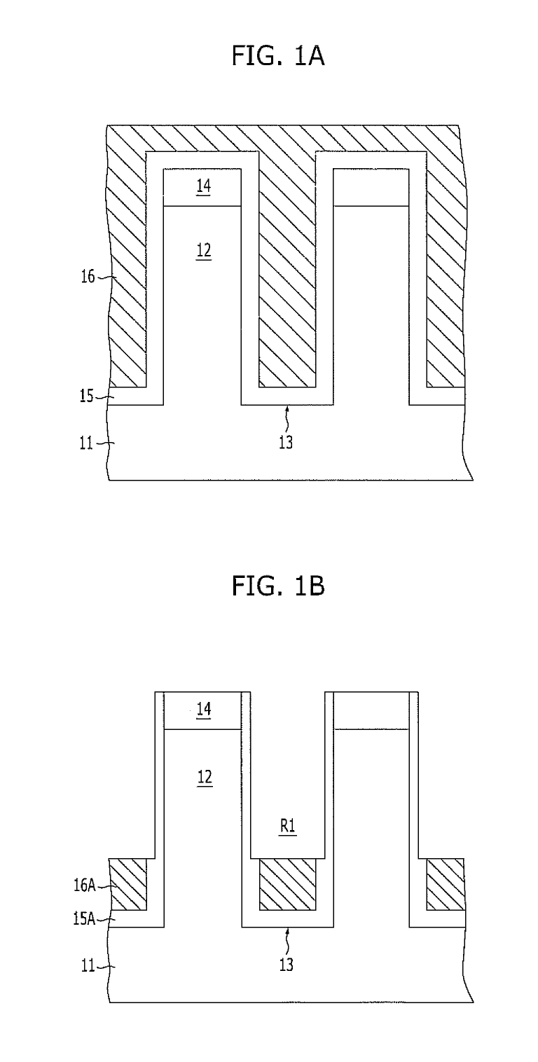

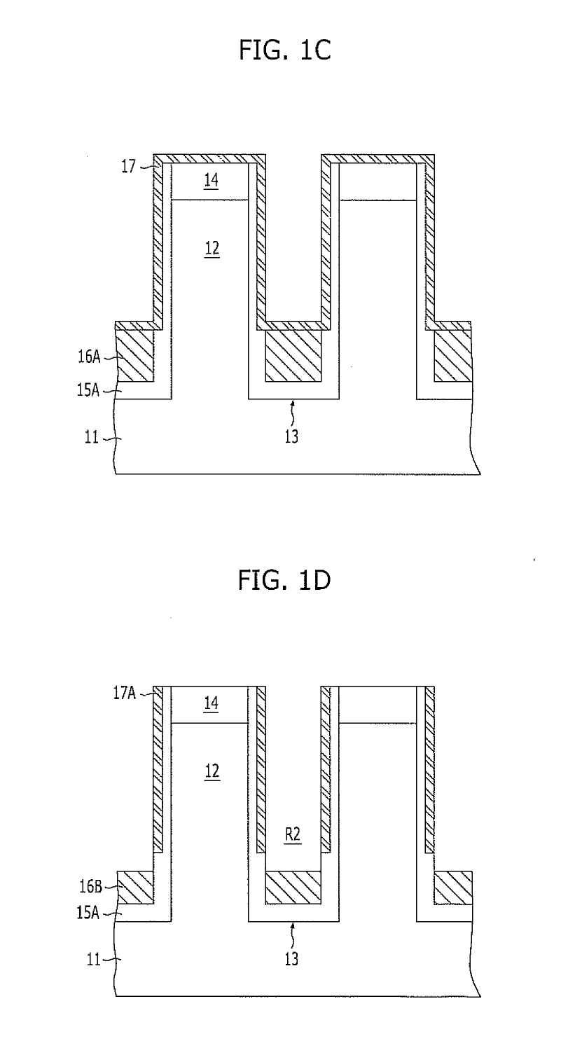

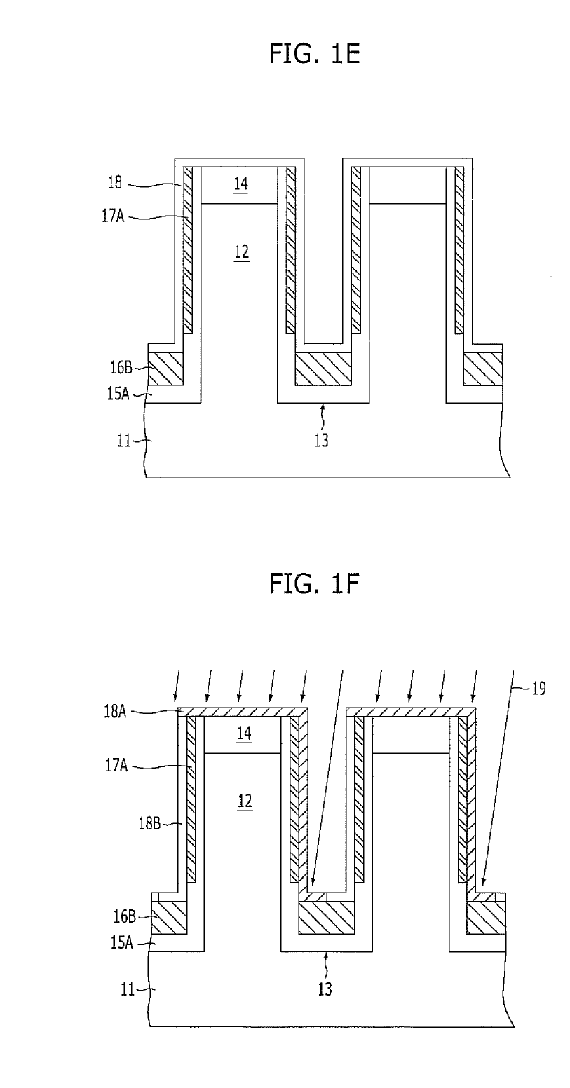

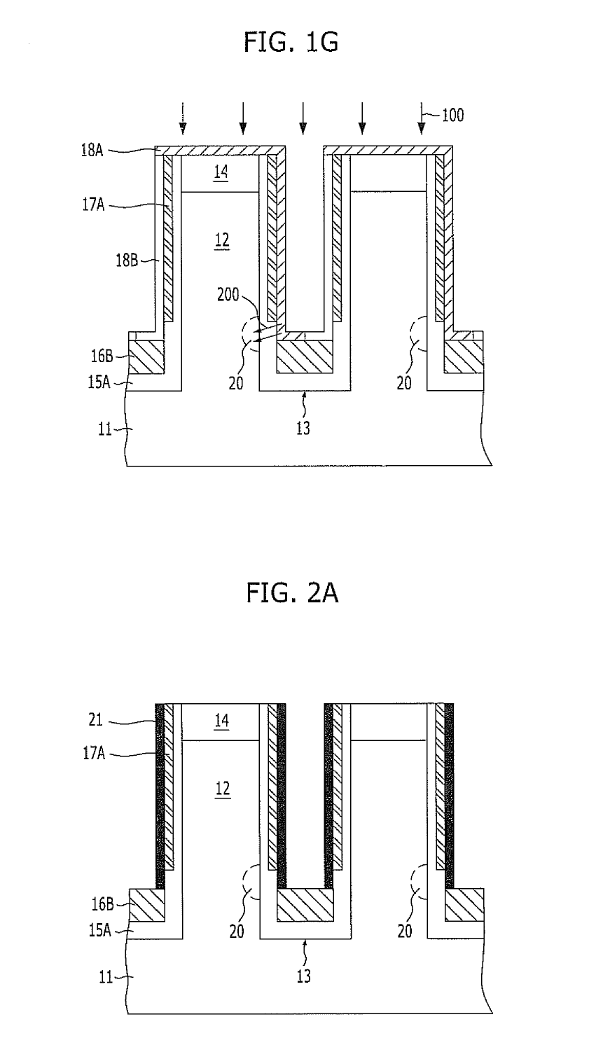

FIGS. 1A to 1G are cross-sectional views illustrating a method for fabricating a semiconductor device in accordance with an embodiment of the present invention.

Referring to FIG. 1A, a plurality of pillars 12 isolated by a plurality of trenches 13 are formed over a substrate 11. The substrate 11 includes a silicon substrate. The plurality of trenches 13 are formed by etching the substrate 11, and the pillars 12 are formed as a result of forming the trenches 13. Since the substrate 11 includes a silicon substrate, the pillars 12 becomes silicon pillars. The pillars 12 extend in a vertical direction from the surface of the substrate 11. The pillars 12 are used as an active region. As is well known, the active region is where a channel, a source, and a drain of a transistor are formed. The pillars 12 have sidewalls. The pillars 12 include a line-type pillar having two or more sidewalls. The pillar 12 may be referred to as an active pillar.

A hard mask layer 14 is formed over the pillar 12. The hard mask layer 14 serves as an etch barrier when the substrate 11 is etched to form the trenches 13. The hard mask layer 14 includes a dielectric material such as an oxide or a nitride. In this embodiment of the present invention, nitride is used as the hard mask layer 14. The hard mask layer 14 includes silicon nitride.

A liner oxide layer 15 is formed along the entire structure including the pillar 12 and the hard mask layer 14. The liner oxide layer 15 is formed of silicon oxide such as LPTEOS (LPCVD Tetra-ethyl-ortho-silicate). The liner oxide layer 15 prevents excessive diffusion of dopants during a subsequent junction formation process, and the liner oxide layer 15 further serves as a buffer for forming a shallow junction. Hereafter, the liner oxide layer 15 is referred to as a buffer layer 15.

A first gap-fill layer 16 is formed on the buffer layer 15 to fill the trenches 13. The first gap-fill layer 16 may include amorphous silicon.

Referring to FIG. 1B, the first gap-fill layer 16 is planarized until the surface of the hard mask layer 14 is exposed. The planarization of the first gap-fill layer 16 may be performed by chemical mechanical polishing (CMP). Subsequently, an etch-back process is performed. After the etch-back process, a first gap-fill layer pattern 16A is recessed to a first height to provide a first recess R1. During the CMP process, the buffer layer 15 on the hard mask layer 14 may be polished. Accordingly, a buffer layer pattern 15A remains to cover both sidewalls of the hard mask layer 14 and both sidewalls of the pillar 12 in the first recess R1. The buffer layer pattern 15A also covers the bottom of the trench 13.

The buffer layer pattern 15A is reduced in thickness by wet etching. Accordingly, the thickness of the buffer layer pattern 15A that remains on the sidewalls of the pillar 12 in the first recess R1 becomes smaller than the thickness of the buffer layer pattern 15A surrounding the first gap-fill layer pattern 16A. As such, the first gap-fill layer pattern 16A filling a portion of the trench 13 serves as a diffusion prevention layer for preventing the diffusion of dopants during the subsequent junction formation process. Hereafter, the first gap-fill layer pattern 16A is referred to as a first diffusion prevention layer 16A.

Referring to FIG. 1C, a liner nitride layer 17 is formed as a dielectric layer on the entire surface of the resultant structure including the first diffusion prevention layer 16A. The liner nitride layer 17 includes nitride such as silicon nitride.

Referring to FIG. 1D, the liner nitride layer 17 is etched to form a liner nitride layer pattern 17A. Subsequently, the first diffusion prevention layer 16A is recessed to a second height using the liner nitride layer pattern 17A as an etch barrier. Accordingly, a second recess R2 is formed. The first diffusion prevention layer that remains at the bottom of the second recess R2 is denoted by reference numeral 16B. As the second recess R2 is formed, the buffer layer pattern 15A between the liner nitride layer pattern 17A and the first diffusion prevention layer 16B is exposed.

As such, the liner nitride layer pattern 17A formed on the sidewalls of the pillar 12 and the hard mask layer 14 prevents dopant diffusion together with the first diffusion prevention layer 1613 during the subsequent junction formation process. Hereafter, the liner nitride layer pattern 17A is referred to as a second diffusion prevention layer 17A.

A first sidewall of the pillar 12 at the buffer pattern 15A exposed between the first and second diffusion prevention layers 16B and 17A becomes a contact formation region.

Referring to FIG. 1E, a liner layer 18 is formed along the entire structure including the second diffusion prevention layer 17A and the first diffusion prevention layer 16B. The liner layer 18 is used as a sacrifice layer for forming a junction in a portion of any one sidewall of the pillar 12 through ion implant and diffusion. The liner layer 18 includes polysilicon. For example, the liner layer 18 may be formed to a thickness of 5 Å to 150 Å.

Referring to FIG. 1F, a first tilt ion implantation process 19 is performed. The first tilt ion implantation process 19 is performed at a designated angle. The designated angle may be adjusted in such a manner that the ion implant is performed within the middle of the liner layer 18 over the first diffusion prevention layer 16B. For example, the first tilt ion implantation process 19 may be performed at an angle of 0.1° to 15°. Ion beams are partially shadowed by the pillars 12. Therefore, a first portion of the liner layer 18 is doped, but a second portion, which does not include the first portion of the liner layer 18, is undoped.

During the first tilt ion implantation process 19, which is performed to form a junction, all kinds of sources including an N-type dopant may be used. For example, the N-type dopant includes P or As. During the first tilt ion implantation process 19, an energy amount of the ion implantation is controlled in such a manner that only the liner layer 18 is selectively doped. For example, the first tilt ion implantation process 19 may be performed at an energy amount of 0.1 KeV to 10 KeV. Furthermore, the first tilt ion implantation process 19 is performed at a high enough concentration to form a junction. For example, the first tilt ion implantation process 19 may be performed at a concentration of 1×10¹⁴ atoms/cm² to 1×10¹⁷ atoms/cm².

Through the first tilt ion implantation process 19, the first portion of the liner layer 18, which includes the top surface of the hard mask layer 14 and the portion of the liner layer 18 that is adjacent to the right side of the hard mask layer 14 and the pillar 12, become an ion-implanted region 18A that is doped with the dopants. The second portion of the liner layer 18, into which no dopants are implanted, becomes a non-implanted region 18B.

Referring to FIG. 1G, a thermal process 100 is performed. The dopants doped in the ion-implanted region 18A of the liner layer are diffused into the pillar 12 through the exposed buffer layer 15A, and the dopants doped in the ion-implanted region 18A are subsequently activated to form a junction 20 in a portion of the sidewall of the pillar 12.

During the thermal process 100, the diffusion of the dopants is suppressed where the first and second diffusion prevention layers 16B and 17A are formed. Therefore, the dopants are diffused into the pillar 12 where the buffer layer pattern 15A is not covered by the first or second diffusion prevention layer 16B and 17A. As a result, the junction 20 is formed in the sidewall of the pillar 12 between the second diffusion prevention layer 17A and the first diffusion prevention layer 16B. In particular, a shallow junction may be formed by the buffer layer pattern 15A formed between the pillar 12 and the liner layer 18, which may prevent a floating body effect.

The thermal process 100 for forming the junction 20 may include one thermal process selected from the group consisting of a furnace thermal process, a rapid thermal annealing (RTA) process, a flash annealing process, and a laser annealing process. The furnace thermal process and the RTA process may be performed under a gas atmosphere using at least one selected from the group consisting of N₂, O₂, Ar, H₂, and NH₃. The previously listed gas atmospheres are used in the furnace thermal process and the RTA process to enhance the diffusion and activation of dopants. The RTA process may include all kinds of thermal processes using a halogen lamp, such as conventional RTA or spike RTA.

As such, the junction 20 is formed in any one sidewall of the pillar 12 before an SSC process. Therefore, although a double side contact occurs due to a process condition during the SSC process, a bridge between bit lines may be prevented. Furthermore, since the buffer layer pattern 15A between the pillar 12 and the liner layer 18 prevents excessive diffusion of the dopants, a shallow junction may be formed. Furthermore, since the first and second diffusion prevention layers 16B and 17A suppress the diffusion of dopants during the formation of the junction 20, the junction 20 may be formed at a uniform region across the entire surface of a wafer. Furthermore, since the ion implant process is used, the difficulty level of the fabrication process may be simplified.

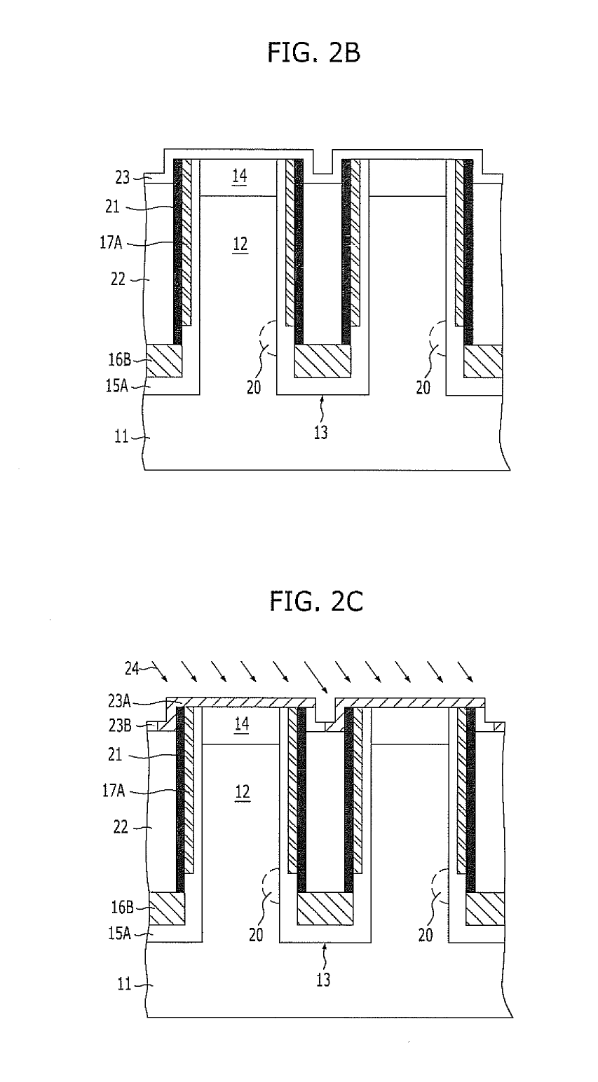

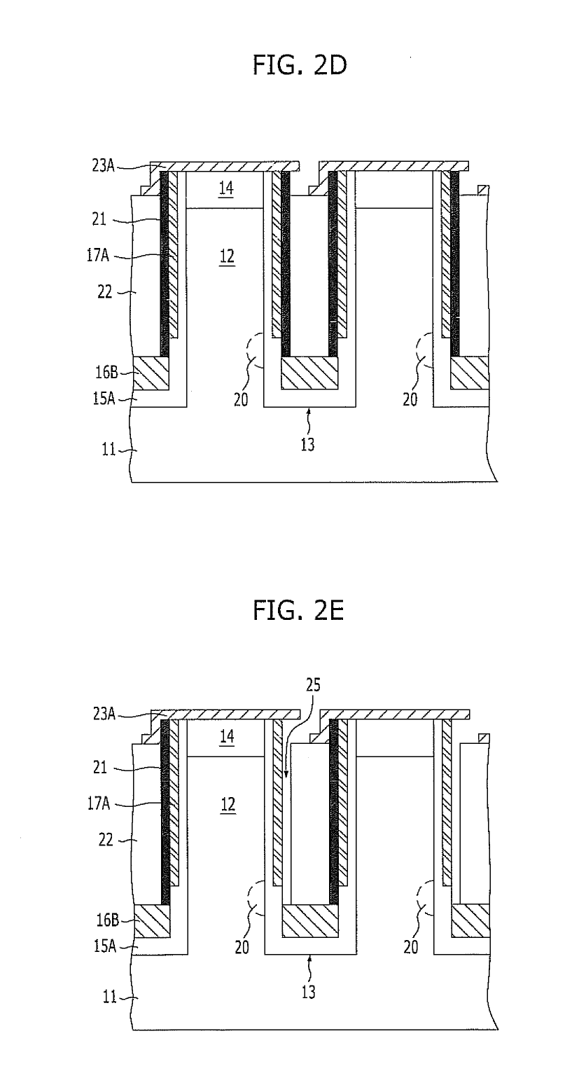

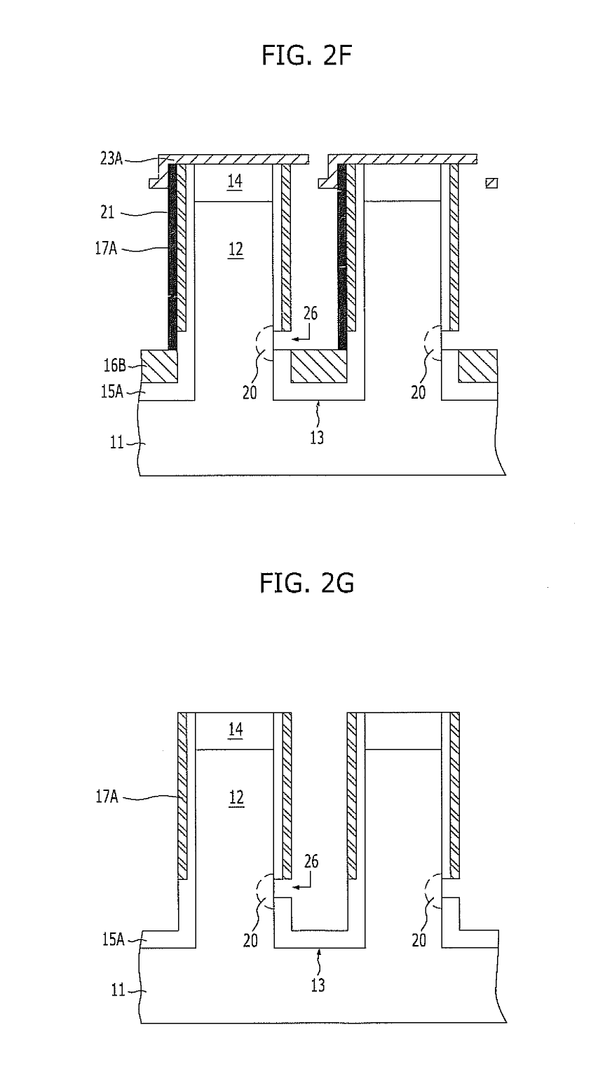

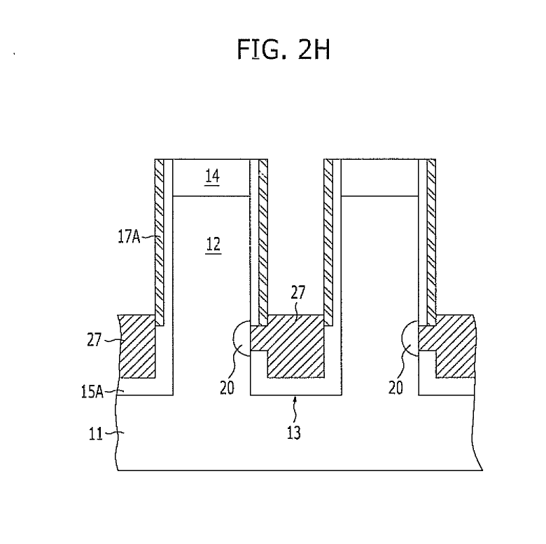

As subsequent processes, an SSC process and a buried bit line process are performed. These processes will be described in detail with reference to FIGS. 2A to 2H.

FIGS. 2A to 2H are cross-sectional views illustrating the SSC process and the buried bit line process, which are performed after the process of FIG. 1G. For illustration purposes, the same reference numerals as those of FIGS. 1A to 1G are used.

Referring to FIG. 2A, the liner layers 18A and 18B are removed after the junction 20 is completely formed. Since the thickness of the liner layers 18A and 18B ranges from 5 Å to 150 Å, the liner layers 18A and 18B may be easily removed. The liner layers 18A and 18B may be removed under a condition that removes silicon because the silicon liner layers have the same etching selectivity, regardless of whether the doping was performed or not. The liner layers 18A and 18B may be removed through wet or dry cleaning.

When the liner layers 18A and 18B are removed, the first diffusion prevention layer 16B formed of silicon may also be partially etched.

A metal nitride layer is conformally formed on the entire surface of the resultant structure including the first diffusion prevention layer 16B. Subsequently, spacer etching is performed to form spacers 21. The spacers 21 are formed on both sidewalls of the pillar 12 in the second recess R2. The spacers 21 include titanium nitride (TiN).

Referring to FIG. 2B, a second gap-fill layer is formed to gap-fill the second recess R2. The second gap-fill layer may include oxide. Furthermore, the second gap-fill layer may include a spin-on dielectric (SOD).

The second gap-fill layer is planarized and subsequently etched back. Accordingly, the recessed second gap-fill layer pattern 22 is formed.

An etch barrier layer 23 is formed on the entire surface of the resultant structure including the second gap-fill layer pattern 22. The etch barrier layer 23 includes undoped polysilicon.

Referring to FIG. 2C, a second tilt ion implantation process 24 is performed. The second tilt ion implantation process 24 is performed at a designated angle to implant dopants. During the second tilt ion implantation process 24, an energy amount of the ion implantation is controlled in such a manner that dopants are implanted, for example, only into the etch barrier layer 23.

The second tilt ion implantation process 24 is performed at an angle of 5° to 30°. Ion beams are partially shadowed by the hard mask layer 14. Therefore, a first portion of the etch barrier layer 23 is doped, but a second portion, which does not include the first portion, of the etch barrier layer 23 is undoped. For example, the ion-implanted dopants may include a P-type dopant, more specifically, boron. In order to implant boron, BF₂ is used as a dopant source. As a result, the second portion of the etch barrier layer 23, which is undoped, is adjacent to the right side of the hard mask layer 14.

Through the second tilt ion implantation process 24, a first portion of the etch barrier layer 23, which includes the top surface of the hard mask layer 14 and a portion of the etch barrier layer 23 adjacent to the left side of the hard mask layer 14, becomes a doped etch barrier layer 23A, which is doped with the dopants. The second portion of the etch barrier layer 23, into which no dopants are implanted, becomes an undoped etch barrier layer 23B.

Referring to FIG. 2D, the undoped etch barrier layer 23B is removed. Here, polysilicon used as the etch barrier layer has a difference in etch rate depending on whether the dopant is doped or not. In particular, undoped polysilicon has a high wet etch rate. Therefore, a high-selectivity chemical capable of wet-etching only the undoped polysilicon is used to remove the undoped etch barrier layer 23B through wet etching or wet cleaning.

When the undoped etch barrier layer 23B is removed in such a manner, the doped etch barrier layer 23A remains.

Referring to FIG. 2E, one of the spacers 21 formed on the pillar 12 is removed. More specifically, the spacer 21 exposed by removing the undoped etch barrier layer 23B is removed. Accordingly, a gap 25 is formed. The spacer 21 is removed by wet etching. As a result, one spacer 21 remains on the opposite side of the pillar 12.

Referring to FIG. 2F, a cleaning process is performed to partially expose the sidewall of the pillar 12 exposed by removing the spacer 21.

The cleaning process includes wet cleaning. The wet cleaning uses HF, buffered oxide etchant (BOE), or the like. When the wet cleaning is used, a part of the liner oxide layer pattern 15A is removed to form an opening 26, which exposes the pillar 12. When the opening 26 is formed, the second gap-fill layer pattern 22 also is removed.

For illustration purposes, the hard mask layer 14, the buffer layer pattern 15A, and the second diffusion prevention layer 17A are collectively referred to as a dielectric layer. Therefore, the dielectric layer provides the opening 26, which partially exposes any one sidewall of the pillar 12.

The opening 26 exposes the junction 20 formed in FIG. 1G.

Referring to FIG. 2G, the spacer 21 and the doped etch barrier layer 23A are removed. When the doped etch barrier layer 23A is removed, the first diffusion prevention layer 16B is also removed.

Referring to FIG. 2H, a buried bit line 27 to be coupled to the junction 20 partially fills the trench 13.

The buried bit line 27 may include a single layer or a stacked layer of a barrier metal and a metal electrode. When the buried bit line 27 includes a stacked layer of a barrier metal and a metal electrode, a barrier metal layer (not illustrated) is formed along the entire structure including the trench 13, and a metal material layer is formed over the barrier metal layer so as to fill the trench 13. Subsequently, the metal material layer and the barrier metal layer are etched through an etch-back process such that the trench 13 is partially filled. At this time, the barrier metal layer may have a stacked structure of titanium and titanium nitride, and the buried bit line 27 may be formed of tungsten.

In accordance with the embodiments of the present invention, before the opening is formed, the junction is formed in any one sidewall of the pillar. Therefore, the occurrence of a bridge between bit lines may be prevented.

Furthermore, a floating body may be prevented, and a uniform junction may be formed.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
etching a substrate to form a pillar isolated by a trench;
forming a buffer layer along the entire structure including the pillar;
forming a diffusion barrier layer that exposes a portion of the buffer layer at a first sidewall of the pillar;
forming a liner layer along the entire structure including the diffusion barrier layer;
selectively ion-implanting dopants into the liner layer; and
forming a junction in the first sidewall of the pillar by diffusing the dopants through a thermal process.

2. The method of claim 1, wherein the ion-implanting of the dopants comprises a tilt ion implantation process.

3. The method of claim 1, wherein the ion-implanting of the dopants comprises an N-type dopant.

4. The method of claim 1, wherein the thermal process comprises one thermal process selected from the group consisting of a furnace thermal process, a rapid thermal annealing (RTA) process, a flash annealing process, and a laser annealing process.

5. The method of claim 4, wherein the furnace thermal process and the RTA process are performed under an atmosphere comprising at least one gas selected from the group consisting of N₂, O₂, Ar, H₂, and NH₃.

6. The method of claim 1, wherein the buffer layer comprises oxide.

7. The method of claim 1, wherein the diffusion barrier layer comprises:
a first diffusion barrier layer filling a portion of the trench; and
a second diffusion barrier layer covering a portion of the first sidewall of the pillar.

8. The method of claim 7, wherein the first diffusion barrier layer comprises silicon.

9. The method of claim 7, wherein the second diffusion barrier layer comprises nitride.

10. The method of claim 7, wherein the forming of the diffusion barrier layer comprises:
forming a silicon layer over the buffer layer to fill the trench;
forming the first diffusion barrier layer by etching the silicon layer so that the first diffusion barrier layer partially fills the trench;
partially etching the exposed buffer layer over the first diffusion barrier layer;
forming a nitride layer along the entire structure including the buffer layer;
forming the second diffusion barrier layer on the sidewalk of the trench by etching the nitride layer; and
exposing a portion of the buffer layer between the first and second diffusion barrier layer by recessing the first diffusion barrier layer to a first height.

11. The method of claim 1, wherein the liner layer comprises polysilicon.

12. The method of claim 1, further comprising, after the forming of the junction:
removing the liner layer;
forming an opening to expose the junction of the pillar; and
forming a buried bit line to be coupled to the junction.

13. The method of claim 12, wherein the forming of the opening comprises:
forming a spacer on the sidewalls of the pillar;
forming a gap-fill layer pattern in the trench;
forming an etch barrier layer on the entire surface of the resultant structure including the gap-fill layer pattern;
selectively ion-implanting dopants into the etch barrier layer;
removing a first portion of the etch barrier layer that is not doped by the dopants;
removing one spacer that is exposed by removing the first portion of the etch barrier layer;
performing a cleaning process to form the opening and expose the first sidewall of the pillar where the junction is formed.

14. A method for fabricating a semiconductor device, comprising:
forming a buffer layer over a substrate;
forming a diffusion barrier layer pattern over the buffer layer to expose a portion of the buffer layer;
forming a liner layer along the entire structure including the diffusion barrier layer;
ion-implanting dopants into the liner layer; and
forming a shallow junction in the substrate by diffusing the dopants through a thermal process.

15. The method of claim 14, wherein the ion-implanting of the dopants comprises an N-type dopant.

16. The method of claim 14, wherein the ion-implanting comprises a tilt ion implantation process.

17. The method of claim 14, wherein the buffer layer comprises oxide.

18. The method of claim 14, wherein the diffusion barrier layer pattern comprises nitride.

19. The method of claim 14, wherein the liner layer comprises polysilicon.
